(19) United States
(12) Patent Application Publication
(10) Pub. No.: US 2026/0291216 A1
(43) Pub. Date: Sep. 24, 2026

(54) INSULATION MONITORING DEVICE (IMD), SYSTEM FOR MONITORING INSULATION AND METHOD FOR MONITORING INSULATION OF IMD

(71) Applicant: LS ELECTRIC CO., LTD., Anyang-si (KR)

(72) Inventors: Changjun KIM, Anyang-si (KR); Minsu PARK, Anyang-si (KR)

(21) Appl. No.: 19/563,376

(22) Filed: Mar. 11, 2026

(30) Foreign Application Priority Data
Mar. 18, 2025 (KR) 10-2025-0034876

(51) Int. Cl. H02H 7/26; G01R 27/18; G01R 31/12; H02H 1/00

(52) U.S. Cl. CPC H02H 7/263; G01R 27/18; G01R 31/1272; H02H 1/0007

(57) ABSTRACT

Provided is an insulation monitoring device, an insulation monitoring system, and an insulation monitoring method, in which insulation of one of a first zone and a second zone is monitored through selective connection to one of an electric path of the first zone between a transformer and a power conversion device and an electric path of the second zone between the power conversion device and a load according to whether the power conversion device is in operation.

### CROSS-REFERENCE TO RELATED APPLICATION

Pursuant to 35 USC § 119(a), this application claims the benefit of the earlier filing date and the right of priority to Korean Patent Application No. 10- 2025-0034876, filed on March 18, 2025, the contents of which are incorporated by reference herein in its entirety.

### FIELD

The disclosure relates to an insulation monitoring device (IMD) that monitors the insulation of a system including a power conversion device.

### BACKGROUND

The technology that forms the background of the disclosure relates to monitoring the insulation of an ungrounded system.

Isolated terra (IT) grounding is a method in which any of power lines is not grounded and grounding is achieved only through an enclosure of a load. The IT grounding method has the advantage of ensuring a continuous operation of a system because there is time to find a site where a ground fault has occurred without stopping the operation of the system even when the ground fault occurs in any one of power lines.

However, the system can be operated even when the ground fault occurs, and thus it is necessary to continuously monitor the insulation status of the power lines even when the system is in operation. In an ungrounded system, an extremely low fault current flows during a ground fault. It is difficult to detect such fault current using a ground fault detection device which is used in a grounded system. In AC systems, ground potential transformers (GPTs) have been used to measure zero-sequence voltage. However, GPT cannot be applied to DC lines, such as those in solar power and energy storage system (ESS). Insulation monitoring devices (IMDs) have been adopted as an alternative for ungrounded systems, as shown in FIG. 1.

The IMD is a device as disclosed in Korean Patent Application Publication No. 10-2024-0147294 (published on October 8, 2024, hereinafter referred to as "Prior Art Document"). The IMD may include a pulse signal generator that is arranged between a ground and a transmission line, forms a circuit between the transmission line and the ground through insulation resistance, which is formed between the transmission line and the ground, and injects a square wave (pulse) signal into the formed circuit, and a detection resistor that detects a voltage according to the square wave signal. When the pulse signal generator applies a signal (voltage Vp) to the ground (protective earth PE), insulation resistance Re is calculated based on a signal (voltage Vm) in which the voltage is distributed by virtual resistance (insulation resistance Re) between an ungrounded line and the ground from the applied signal Vp and internal resistance Ri of the IMD, thereby enabling the insulation status of the ungrounded line to be monitored.

In recent times, as the penetration rate of renewable energy increases, there is a trend toward building power grids to manage loads and stabilize renewable energy. As part of this trend, energy storage devices (ESS) are being installed in the power grids. The ESS can efficiently and stably supply power to loads by storing excessively generated power and discharging the stored power when there is an energy shortage in the power grids.

As an ESS is installed in a power grid, the ESS is connected to an ungrounded line through which alternating current (AC) supplied from a power source flows. In this case, a line section from the power source to the ESS may be connected to a line section connecting a power conditioning system (PCS) arranged in the ESS to a battery.

When a power system including the PCS, such as an ESS system, is connected to an ungrounded system, only one IMD should operate per system. When several IMDs are installed on the same line, an insulation resistance value measured by each IMD is expressed as a combined resistance value of insulation resistance between an actual line to be measured and the ground and internal resistance of other installed IMDs, which makes accurate measurement impossible. Furthermore, when a plurality of IMDs performs the measurement at the same time, normal measurement operation is not allowed due to interference between the measurement waveforms transmitted from a signal generator of each IMD to the PE for measurement. Therefore, as shown in FIG. 2, IMDs must be installed on an AC side, which is the front end of the PCS, a DC side, which is the rear end of the PCS, and a load side, respectively. In this case, a coupler (coupling device) is utilized for voltage expansion on the DC side and the load side corresponding to DC power. When operating at a higher voltage than the IMD unit alone, such a coupler is further installed.

In this way, when the IMD is installed, the measurement range of the system in which the IMD is installed changes depending on whether the PCS is in operation. As shown in FIG. 2, when the PCS is not in operation, the AC side and DC side systems are separated, and the IMDs on the AC side (monitoring range 1), DC side (monitoring range 2), and load side (monitoring range 3) each monitor insulation. As shown in FIG. 3, when the PCS is in operation, the AC side and DC side become the same system, and one IMD on the load side monitors insulation.

As such, IMDs had to be installed on the AC side, DC side, and load side of the system, but this large number of installations increased installation costs and inconvenience, and there was a limitation that installation space was insufficient. In particular, when the PCS is in operation, the IMDs on the AC and DC sides do not work, raising concerns about the necessity and efficiency of installing the IMDs throughout the entire system.

### SUMMARY

The disclosure aims to overcome the aforementioned limitations of the related art.

Accordingly, an aspect of the disclosure is to provide an embodiment capable of reducing the number of IMDs arranged in a system.

Another aspect of the disclosure is to provide an embodiment capable of performing insulation monitoring on AC and DC sides while reducing the number of IMDs.

An aspect of the disclosure, which aims to solve the above-described problem, is to monitor insulation of a plurality of systems through an IMD arranged in one system.

More specifically, an aspect of the disclosure is to enable an IMD on an AC side to monitor insulation on a DC side by utilizing a coupler arranged on the DC side.

Such technical features can be applied to and implemented in insulation monitoring devices, insulation monitoring systems, power systems, power conversion systems, and insulation monitoring methods, and this specification aims to provide embodiments of insulation monitoring devices, insulation monitoring systems, and insulation monitoring methods that use the above technical features as a means for solving the relevant problems.

An embodiment of the insulation monitoring device which is an insulation monitoring device configured to monitor insulation of a system, includes a first channel unit connected to an electric path of a first zone between a transformer and a power conversion device in the system, a second channel unit connected to a coupling device connected to an electric path of a second zone between the power conversion device and a load in the system, and a monitoring unit connected to a ground that is not connected to the electric path of the system, connected to one of the first channel unit and the second channel unit according to an operation signal transmitted from the power conversion device, and configured to apply a predetermined signal to one of the ground and the connected channel unit, receive a measurement signal corresponding to the predetermined signal from another channel unit, and determine an insulation status of a zone corresponding to the connected channel unit based on the measurement signal.

In an embodiment of the insulation monitoring device, a first protection device may be arranged in the first zone to connect or disconnect the transformer to or from the power conversion device, and the first channel unit may be connected to an electric path between the transformer and the first protection device.

In an embodiment of the insulation monitoring device, one of the first channel unit and the second channel unit may be connected to the monitoring unit while the first protection device is open.

In an embodiment of the insulation monitoring device, a second protection device may be arranged in the second zone to connect or disconnect the power conversion device to or from the load, and the second channel unit may be connected to an electric path between the power conversion device and the second protection device through the coupling device.

In an embodiment of the insulation monitoring device, one of the first channel unit and the second channel unit may be connected to the monitoring unit while the second protection device is open.

In an embodiment of the insulation monitoring device, the first channel unit and the second channel unit may be disconnected from the monitoring unit in a state where a first protection device arranged in the first zone to connect or disconnect the transformer to or from the power conversion device and a second protection device arranged in the second zone to connect or disconnect the power conversion device to or from the load are closed.

In an embodiment of the insulation monitoring device, the monitoring unit may be connected to the first channel unit to determine an insulation status of the first zone based on the measurement signal received from the ground or the first channel unit when receiving a first operation signal from the power conversion device, and may be connected to the second channel unit to determine an insulation status of the second zone based on the measurement signal received from the ground or the second channel unit when receiving a second operation signal from the power conversion device.

In an embodiment of the insulation monitoring device, the monitoring unit may calculate magnitude of insulation resistance of a zone corresponding to the connected channel unit based on the measurement signal, and determine an insulation status of the zone corresponding to the connected channel unit based on the magnitude of the insulation resistance.

An embodiment of the insulation monitoring system includes a transformer configured to transmit a three-phase alternating current (AC) voltage, a power conversion device configured to receive the AC voltage from the transformer and convert the AC voltage into a direct current (DC) voltage, a first insulation monitoring device configured to monitor insulation of a primary-side electric path of the power conversion device, a coupling device configured to receive a signal from a secondary-side electric path of the power conversion device, and a second insulation monitoring device configured to monitor insulation of a load-side electric path receiving the DC voltage from the power conversion device, wherein the first insulation monitoring device includes a first channel unit configured to receive a signal from the primary-side electric path, a second channel unit configured to receive a signal, which is received from the secondary-side electric path, from the coupling device, a signal unit configured to apply a predetermined signal to a ground which is not connected to the primary-side electric path and the secondary-side electric path, a control unit connected to one of the first channel unit and the second channel unit, and configured to receive a measurement signal corresponding to the predetermined signal from the connected channel unit, and determine an insulation status of an electric path corresponding to the connected channel unit based on the measurement signal, and a connecting unit configured to connect the first channel unit to the control unit when monitoring the primary-side electric path, and connect the second channel unit to the control unit when monitoring the secondary-side electric path.

In an embodiment of the insulation monitoring system, the insulation monitoring system may further include a first protection device configured to connect or disconnect the transformer to or from the power conversion device in the primary-side electric path, and a second protection device configured to connect or disconnect the power conversion device to or from the load in the secondary-side electric path, the first insulation monitoring device may be connected to an electric path between the transformer and the first protection device, the coupling device may be connected to an electric path between the power conversion device and the second protection device, and the first insulation monitoring device may be connected to an electric path between the second protection device and the load.

In an embodiment of the insulation monitoring system, the connecting unit may disconnect the first channel unit and the second channel unit from the control unit when the first protection device connects the transformer to the power conversion device and the second protection device connects the power conversion device to the load.

In an embodiment of the insulation monitoring system, the connecting unit may include a first switching portion configured to connect the first channel unit to the control unit when monitoring the primary-side electric path, and disconnect the first channel unit from the control unit when monitoring the secondary-side electric path, and a second switching portion configured to connect the second channel unit to the control unit when monitoring the secondary-side electric path and disconnect the second channel unit from the control unit when monitoring the primary-side electric path.

An embodiment of the insulation monitoring method, which is an insulation monitoring method of an insulation monitoring device, which includes a first channel unit configured to receive a signal from a first electric path between a transformer and a power conversion device in a system, a second channel unit configured to receive a signal from a coupling device that receives a signal from a second electric path between the power conversion device and a load in the system, and a monitoring unit configured to apply a predetermined signal to an electric path of the system to determine an insulation status of one of the first electric path and the second electric path based on a signal received from one of the first channel unit and the second channel unit, includes deciding a monitoring mode of the insulation monitoring device, connecting to one of the first channel unit and the second channel unit according to the monitoring mode, applying the predetermined signal to the ground to receive a measurement signal corresponding to the predetermined signal from a connected channel unit, and determining an insulation status of an electric path connected to the connected channel unit based on the measurement signal.

In an embodiment of the insulation monitoring method, the monitoring mode may be a mode for monitoring one of the first electric path and the second electric path while the power conversion device is not in operation.

In an embodiment of the insulation monitoring method, the connecting step may be configured to connect to the first channel unit when the monitoring mode is a mode for monitoring the first electric path, and to connect to the second channel unit when the monitoring mode is a mode for monitoring the second electric path.

In an embodiment of the insulation monitoring method, the determining step may be configured to calculate magnitude of insulation resistance of an electric path connected to the connected channel unit based on the measurement signal, and determine an insulation status of the electric path corresponding to the connected channel unit based on the magnitude of the insulation resistance.

The embodiments of the insulation monitoring device, insulation monitoring system, and insulation monitoring method described above are not limited to those described above, and may include embodiments described in the specific description to be described below or embodiments that can be inferred/derived from the specific description.

According to the embodiments of the insulation monitoring device, insulation monitoring system, and insulation monitoring method described above, an IMD on an AC side monitors the insulation on a DC side by utilizing a coupler arranged on the DC side, thereby enabling an IMD arranged on the DC side to be replaced with the IMD on the AC side.

Accordingly, the IMD arranged on the DC side can be excluded, which has the effect of enabling insulation monitoring on the AC side and DC side while reducing the number of IMDs arranged in the system.

By reducing the number of IMDs installed in the system, installation costs and inconveniences can be reduced, and an installation space can be secured.

By reducing the number of IMDs installed in the system, an insulation monitoring system can be established more conveniently and easily.

The embodiments of the insulation monitoring device, insulation monitoring system, and insulation monitoring method described above are not limited to those described above, and may include embodiments described in the specific description to be described below or effects that can be inferred/derived from the specific description.

### BRIEF DESCRIPTION OF THE DRAWINGS

FIG. 1 is a schematic diagram of a typical insulation monitoring device (IMD).

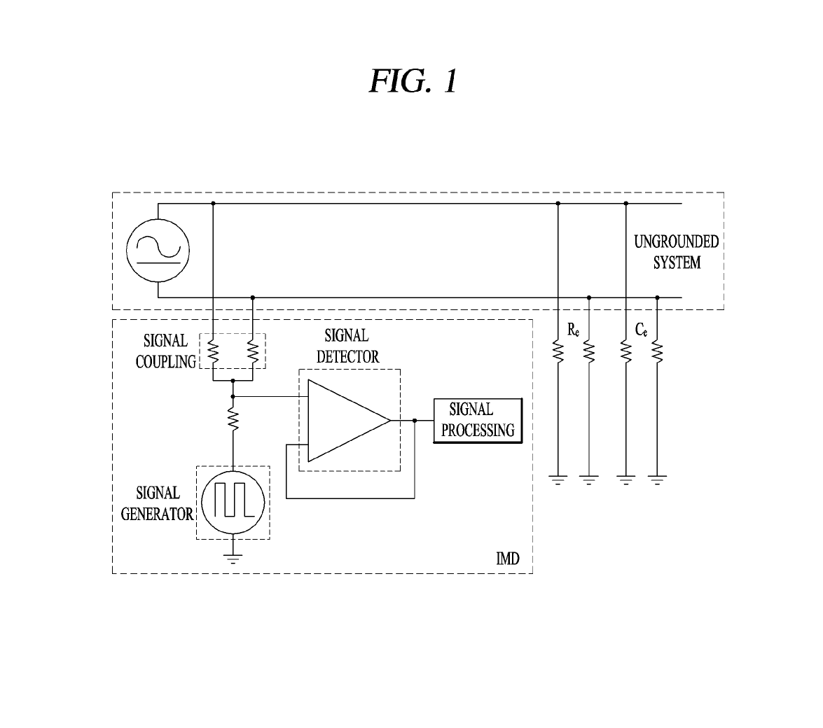

FIG. 2 is a schematic diagram 1 for insulation monitoring of a system including the related art power conversion device and a load.

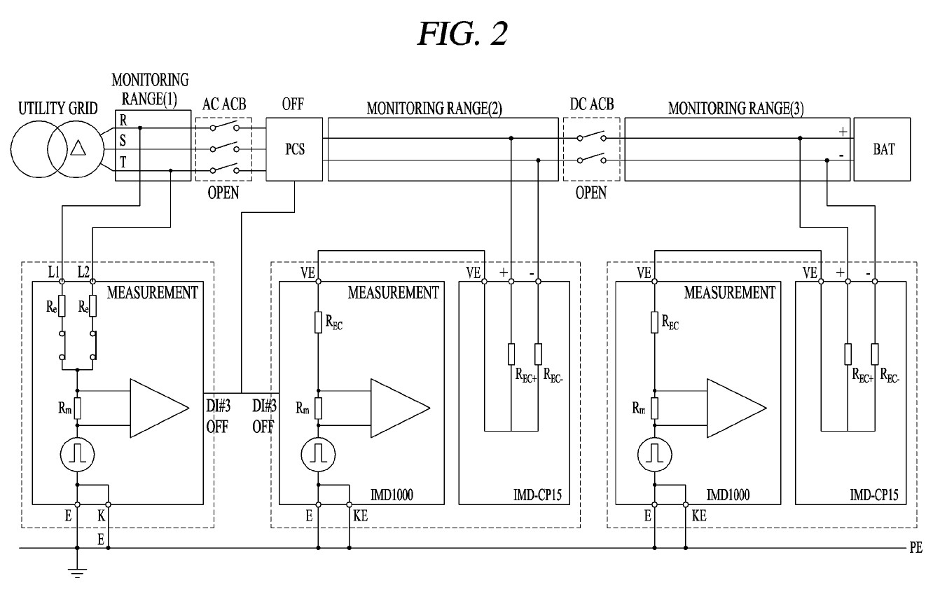

FIG. 3 is a schematic diagram 2 for insulation monitoring of a system including the related art power conversion device and a load.

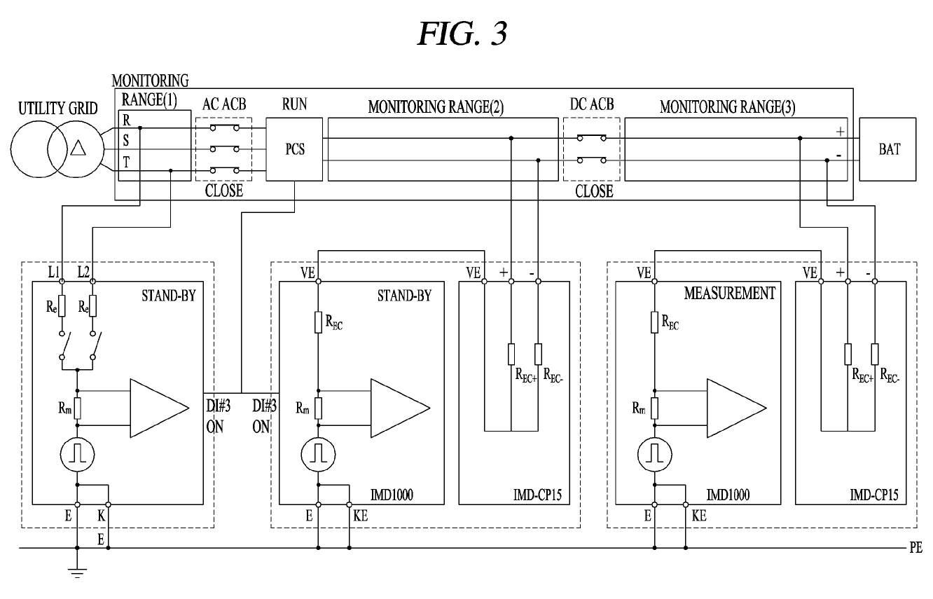

FIG. 4 is a schematic diagram of an insulation monitoring device (IMD) and an insulation monitoring system according to an embodiment.

FIG. 5 is an exemplary diagram 1 showing a specific operation example of an IMD and an insulation monitoring system according to an embodiment.

FIG. 6 is an exemplary diagram 2 showing a specific operation example of an IMD and an insulation monitoring system according to an embodiment.

FIG. 7 is an exemplary diagram 3 showing a specific operation example of an IMD and an insulation monitoring system according to an embodiment.

FIG. 8 is a flowchart of an insulation monitoring method according to an embodiment.

### DETAILED DESCRIPTION

Hereinafter, embodiments of an insulation monitoring device (IMD), an insulation monitoring system, and an insulation monitoring method will be described in detail with reference to the attached drawings. However, when it is determined that a specific description of a related known technology may obscure the gist of the embodiments in describing the embodiments, the detailed descriptions thereof will be omitted, and among the omitted descriptions, the basic configuration of the insulation monitoring device, the operating principle, the configuration of a grid system, and the operating principle and each configuration of the grid system may refer to the above-mentioned prior art document.

The accompanying drawings are used to help easily understand embodiments of the disclosure and it should be understood that the idea of the disclosure is not limited by the accompanying drawings. The idea of the disclosure should be construed to extend to any alterations, equivalents, and substitutes besides the accompanying drawings.

### Insulation monitoring device (IMD)

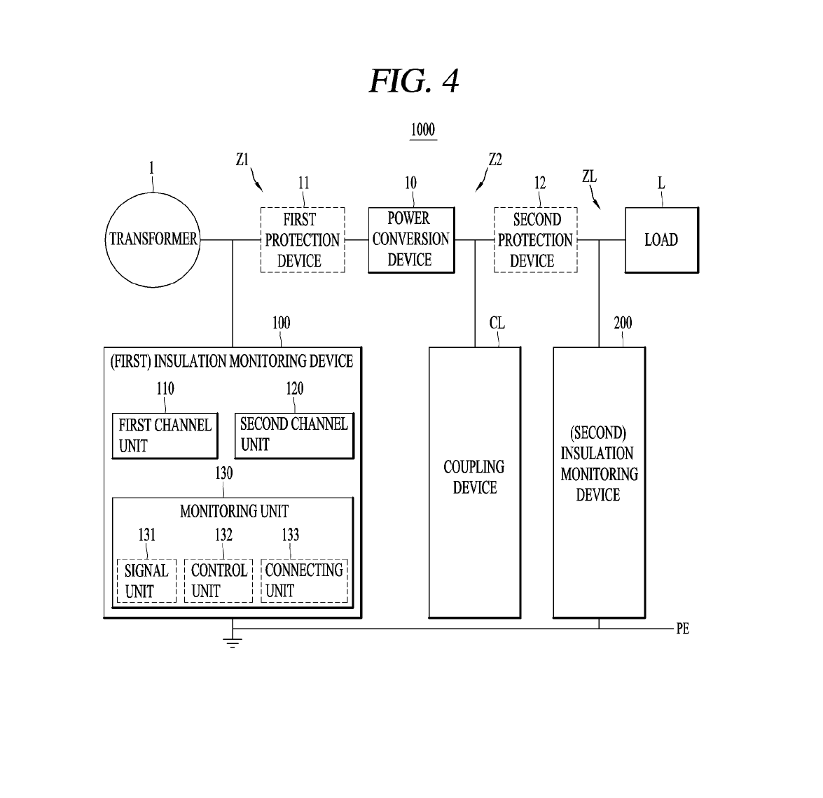

An insulation monitoring device (IMD) 100 according to an embodiment may be a device that monitors insulation of a (power) system 1000 as shown in FIG. 4.

The system 1000 may be a power grid in which a transformer 1 transforms AC power supplied from a power supply network and supplies the transformed power to a power conversion device 10, and the power conversion device 10 converts the received power and supplies the converted power to a load L.

The transformer 1, the power conversion device 10, and the load L may each be connected via a plurality of electric paths, so that power can flow.

In this way, the system 1000 in which the transformer 1, the power conversion device 10, and the load L are connected may be a non-grounded system with no ground connection.

The transformer 1 may be a multi-winding transformer.

The transformer 1 may be connected to at least one power grid to supply power to each of the at least one power grid.

Here, each of the at least one power grid may include the power conversion device 10.

Accordingly, the at least one power grid may be divided based on whether or not the power conversion device 10 is included.

The transformer 1 may transform a voltage of AC power and transmit the transformed voltage to the power conversion device 10 arranged in the corresponding power grid.

The power conversion device 10 may be a power conditioning system (PCS).

The power conversion device 10 may convert AC power into DC power.

Accordingly, the power conversion device 10 can convert AC power supplied from the transformer 1 into DC power and supply the converted DC power to the load L.

That is, AC power can flow in an electric path Z1 between the transformer 1 and the power conversion device 10, and DC power can flow in an electric path Z2 between the power conversion device 10 and the load L.

In this way, the system 1000 may be divided into a first zone Z1 between the transformer 1 and the power conversion device 10 through which AC power flows, and a second zone Z2 between the power conversion device 10 and the load L through which DC power flows.

The system 1000 may include insulation monitoring devices 100 and 200 installed in the zones Z1 and Z2, respectively, to perform insulation monitoring.

The insulation monitoring device 100 according to the embodiment is a device that monitors insulation occurring in an electric path of the first zone Z1 of the plurality of zones of the system 1000, and may be configured as a separate device from a coupling device CL and a second insulation monitoring device 200 installed in the second zone Z2.

The insulation monitoring device 100 includes a first channel unit 110, a second channel unit 120, and a monitoring unit 130.

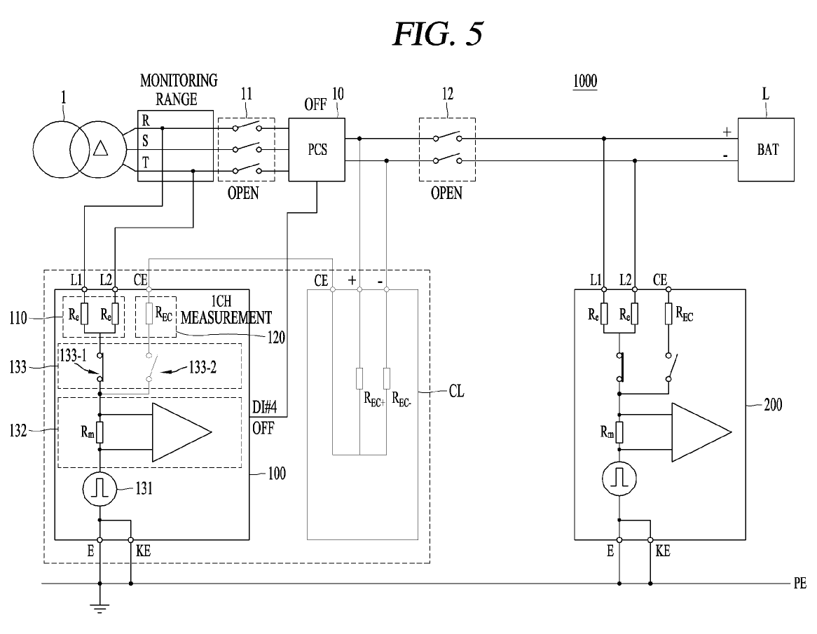

In this way, the specific configuration of the insulation monitoring device 100 including the first channel unit 110, the second channel unit 120, and the monitoring unit 130 may be as shown in FIGS. 5 to 7.

In the insulation monitoring device 100, the first channel unit 110 is connected to an electric path of the first zone Z1 between the transformer 1 and the power conversion device 10 of the system 1000.

The first channel unit 110 may include a plurality of terminals L1 and L2 through which signals are input and output in the insulation monitoring device 100.

The first channel unit 110 may also include a plurality of resistors Re on paths through which signals are input and output.

The first channel unit 110 may be connected to at least two electric paths R and T among electric paths of the first zone Z1 through the plurality of terminals L1 and L2, to receive signals from the electric paths of the first zone Z1 or output signals to the electric paths of the first zone Z1.

When the first channel unit 110 receives a signal from the electric path of the first zone Z1, the first channel unit 110 may transmit the received signal to the monitoring unit 130.

When receiving a signal from the monitoring unit 130, the first channel unit 110 may also output the received signal to the electric path of the first zone Z1.

In the insulation monitoring device 100, the second channel unit 120 is connected to a coupling device CL, which is connected to the electric path of the second zone Z2 between the power conversion device 10 and the load L in the system 1000.

The second channel unit 120 may include a coupling terminal CE through which signals are input and output in the insulation monitoring device 100.

The second channel unit 120 may also include a resistor Re in a path through which a signal is input and output.

The second channel unit 120 may be connected to the coupling device CL through the coupling terminal CE, to receive a signal from the coupling device CL or output a signal to the coupling device CL.

The coupling device CL may be connected to the electric paths + and - of the second zone Z2, to receive signals from the electric paths of the second zone Z2 or output signals to the electric paths of the second zone Z2.

The coupling device CL may include resistors Rec+ and Rec- in paths through which signals are input and output.

Upon receiving a signal from the electric path of the second zone Z2, the coupling device CL may transmit the received signal to the second channel unit 120, and upon receiving a signal from the second channel unit 120, the coupling device CL may output the received signal to the electric path of the second zone Z2.

When the second channel unit 120 receives a signal from the coupling device CL, the second channel unit 110 may transmit the received signal to the monitoring unit 130.

When receiving a signal from the monitoring unit 130, the second channel unit 120 may also output the received signal to the coupling device CL.

In the insulation monitoring device 100, the monitoring unit 130 is connected to a ground PE that is not connected to the electric path of the system 1000, and is connected to one of the first channel unit 110 and the second channel unit 120 according to an operation signal received from the power conversion device 10, to apply a predetermined signal to one of the ground PE and the connected channel unit, receive a measurement signal corresponding to the predetermined signal from the other, and determines an insulation status of a zone corresponding to the connected channel unit based on the measurement signal.

That is, the monitoring unit 130 may be connected to one of the first channel unit 110 and the second channel unit 120 while connected to the ground PE. Accordingly, the monitoring unit 130 may apply the predetermined signal to one of the ground PE and the connected channel unit, receive the measuring signal from the other, and determine the insulation status of one of the first zone Z1 and the second zone Z2 based on the measuring signal.

For example, when applying the predetermined signal to the ground PE while the monitoring unit 130 is connected to the first channel unit 110, the predetermined signal may be applied to the monitoring unit 130 in the form of the measurement signal sequentially via the ground PE, a virtual electric path between the ground PE and the system 1000, the electric path of the first zone Z1, and the first channel unit 110, such that the monitoring unit 130 can determine the insulation status of the first zone Z1 based on the measurement signal.

On the other hand, when applying the predetermined signal to the first channel unit 110 while the monitoring unit 130 is connected to the first channel unit 110, the predetermined signal may be applied to the monitoring unit 130 in the form of the measurement signal sequentially via the first channel unit 110, the electric path of the first zone Z1, the virtual electric path between the ground PE and the system 1000, and the ground PE, such that the monitoring unit 130 can determine the insulation status of the first zone Z1 based on the measurement signal.

In another example, when applying the predetermined signal to the ground PE while the monitoring unit 130 is connected to the second channel unit 120, the predetermined signal may be applied to the monitoring unit 130 in the form of the measurement signal sequentially via the ground PE, the virtual electric path between the ground PE and the system 1000, the electric path of the second zone Z2, the coupling device CL, and the second channel unit 120, such that the monitoring unit 130 can determine the insulation status of the second zone Z2 based on the measurement signal.

On the other hand, when applying the predetermined signal to the second channel unit 120 while the monitoring unit 130 is connected to the second channel unit 120, the predetermined signal may be applied to the monitoring unit 130 in the form of the measurement signal sequentially via the second channel unit 120, the coupling device CL, the electric path of the second zone Z2, the virtual electric path between the ground PE and the system 1000, and the ground PE, such that the monitoring unit 130 can determine the insulation status of the second zone Z2 based on the measurement signal.

That is, the insulation monitoring device 100 can selectively determine the insulation status of any one of the first zone Z1 and the second zone Z2 by the configuration in which the first channel unit 110 is connected to the electric path of the first zone Z1, the second channel unit 120 is connected to the coupling device CL connected to the electric path of the second zone Z2, and the monitoring unit 130 is connected to one of the first channel unit 110 and the second channel unit 120.

Accordingly, insulation monitoring of two zones, namely, the first zone Z1 and the second zone Z2, can be performed using one insulation monitoring device 100.

The monitoring unit 130 may include a signal unit 131 that applies the predetermined signal to the ground PE or the connected channel unit, a control unit 132 that receives the measurement signal from the ground PE or the connected channel unit and determines the insulation status of a zone corresponding to the connected channel unit based on the measurement signal, and a connecting unit 133 that connects or disconnects one of the first channel unit 110 and the second channel unit 120 to or from the control unit 132.

The signal unit 131 may include a signal generator.

The signal unit 131 may be controlled by the control unit 132.

The signal unit 131 may generate the predetermined signal and apply the predetermined signal to the ground PE or the connected channel unit.

The control unit 132 may include a computing device.

The control unit 132 may control each of the signal unit 131 and the connecting unit 133.

The control unit 132 may be connected to one of the first channel unit 110 and the second channel unit 120 by the connecting unit 133, and may determine the insulation status of the zone corresponding to the connected channel unit based on the measurement signal received from the ground PE or the connected channel unit.

The connecting unit 133 may include a switching device.

The connecting unit 133 may be controlled by the control unit 132.

The connecting unit 133 may include a first switching portion 133-1 that is arranged between the first channel unit 110 and the control unit 132 to connect or disconnect the first channel unit 110 to or from the control unit 132 according to a switching operation, and a second switching portion 133-2 that is arranged between the second channel unit 120 and the control unit 132 to connect or disconnect the second channel unit 120 to or from the control unit 132 according to a switching operation.

Here, the connection may mean that two objects are electrically connected, and the disconnection may mean that two objects are electrically disconnected. In the following description, connection and disconnection are used as such meaning.

Each of the first switching portion 133-1 and the second switching portion 133-2 may connect two objects on opposite sides during a closing operation, while disconnecting the two objects on the opposite sides during an opening operation.

In this case, one of the first switching portion 133-1 and the second switching portion 133-2 may be open when the other is closed.

That is, one of the first switching portion 133-1 and the second switching portion 133-2 of the connecting unit 133 may be closed.

Accordingly, the monitoring unit 130 can be connected to one of the first channel unit 110 and the second channel unit 120.

The monitoring unit 130 may selectively determine the insulation status of any one of the first zone Z1 and the second zone Z2 in a manner that the signal unit 131 applies the predetermined signal to one of the ground PE and the connected channel unit, the control unit 132 receives the measurement signal from the other of the ground PE and the connected channel unit, to which the predetermined signal has not been applied, and determines the insulation status of a zone corresponding to the connected channel unit based on the measurement signal, and the connecting unit 133 connects or disconnects the control unit 132 to or from one of the first channel unit 110 and the second channel unit 120.

For convenience of explanation, the following description will be given under assumption that the monitoring unit 130 includes the signal unit 131, the control unit 132, and the connecting unit 133.

Meanwhile, the system 1000 may include a first protection device 11 that connects or disconnects the transformer 1 to or from the power conversion device 10 in the first zone Z1.

The first protection device 11 may be an AC-only protection device.

The first protection device 11 may be a protection device that connects or disconnects two objects by closing or opening contacts connected to electric paths of the two objects on opposite sides.

The first protection device 11 may connect the electric path between the two objects during closing operation, and disconnect the electric path between the two objects during opening operation.

The first protection device 11 may be, for example, an air circuit breaker (ACB).

The first protection device 11 may perform a closing operation or an opening operation based on a signal received from the power conversion device 10, a control device controlling the power conversion device 10, or an operating device of the system 1000.

When the first protection device 11 is arranged between the transformer 1 and the power conversion device 10, the first channel unit 110 may be connected to the electric path between the transformer 1 and the first protection device 11.

That is, the insulation monitoring device 100 can monitor the insulation of the electric path between the transformer 1 and the first protection device 11 among electric paths in the first zone Z1.

One of the first channel unit 110 and the second channel unit 120 may be connected to the monitoring unit 130 when the first protection device 11 is open.

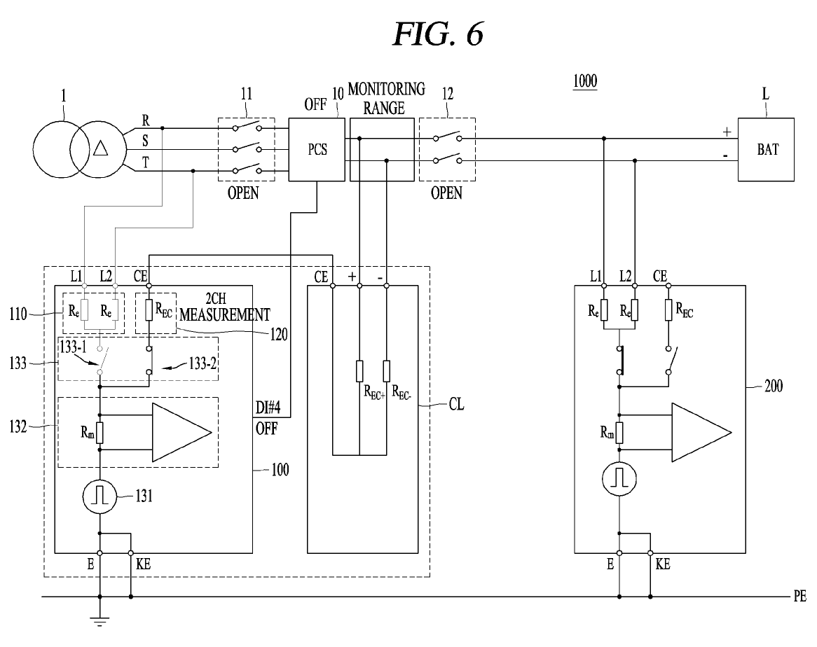

That is, as shown in FIGS. 5 and 6, one of the first channel unit 110 and the second channel unit 120 may be connected to the monitoring unit 130 while the transformer 1 and the power conversion device 10 are disconnected.

Accordingly, when the first protection device 11 is open and the transformer 1 and the power conversion device 10 are disconnected, any one of the first channel unit 110 and the second channel unit 120 can be connected to the monitoring unit 130, enabling the insulation monitoring device 100 to monitor the insulation of one of the first zone Z1 and the second zone Z2.

The first channel unit 110 and the second channel unit 120 may not be connected to the monitoring unit 130 when the first protection device 11 is closed.

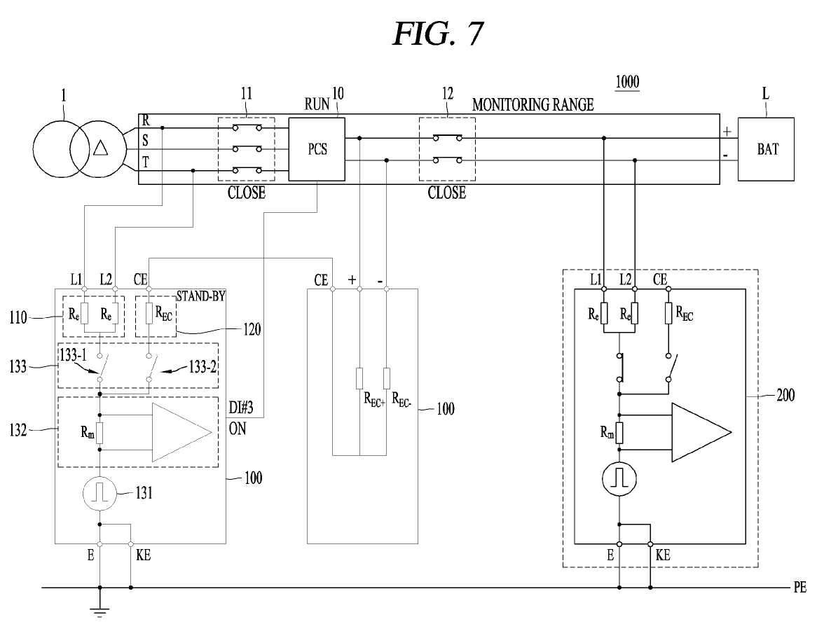

That is, as shown in FIG. 7, the first channel unit 110 and the second channel unit 120 may not be connected to the monitoring unit 130 while the transformer 1 and the power conversion device 10 are connected.

Accordingly, when the first protection device 11 is closed and the transformer 1 and the power conversion device 10 are connected, the first channel unit 110 and the second channel unit 120 may not be connected to the monitoring unit 130, suppressing the insulation monitoring device 100 from monitoring the insulation of the first zone Z1 and the second zone Z2.

The system 1000 may also include a second protection device 12 that connects or disconnects the power conversion device 10 to or from the load L in the second zone Z2.

The second protection device 12 may be an DC-only protection device.

The second protection device 12 may be a protection device that connects or disconnects two objects by closing or opening contacts connected to an electric path between the two objects on opposite sides.

The second protection device 12 may connect the electric path between the two objects during closing operation, and disconnect the electric path between the two objects during opening operation.

The second protection device 12 may be, for example, an air circuit breaker (ACB).

The second protection device 12 may perform a closing operation or an opening operation based on a signal received from the power conversion device 10, a control device controlling the power conversion device 10, or an operating device of the system 1000.

When the second protection device 12 is arranged between the power conversion device 10 and the load L, the second channel unit 120 may be connected to the electric path between the power conversion device 10 and the second protection device 12 through the coupling device CL.

That is, the coupling device CL may be connected to the electric path between the power conversion device 10 and the second protection device 12, and the second channel unit 120 may be connected to the coupling device CL so as to be connected to the electric path between the power conversion device 10 and the second protection device 12 through the coupling device CL.

Accordingly, the insulation monitoring device 100 can monitor the insulation of the electric path between the power conversion device 10 and the second protection device 12 among the electric paths in the second zone Z2.

One of the first channel unit 110 and the second channel unit 120 may be connected to the monitoring unit 130 when the second protection device 12 is open.

That is, as shown in FIGS. 5 and 6, one of the first channel unit 110 and the second channel unit 120 may be connected to the monitoring unit 130 while the power conversion device 01 and the load L are disconnected.

Accordingly, when the second protection device 12 is open and the power conversion device 10 and the load L are disconnected, any one of the first channel unit 110 and the second channel unit 120 can be connected to the monitoring unit 130, enabling the insulation monitoring device 100 to monitor the insulation of one of the first zone Z1 and the second zone Z2.

The first channel unit 110 and the second channel unit 120 may not be connected to the monitoring unit 130 when the second protection device 12 is closed.

That is, as shown in FIG. 7, the first channel unit 110 and the second channel unit 120 may not be connected to the monitoring unit 130 while the power conversion device 10 and the load L are connected.

Accordingly, when the second protection device 12 is closed and the power conversion device 10 and the load L are connected, the first channel unit 110 and the second channel unit 120 may not be connected to the monitoring unit 130, suppressing the insulation monitoring device 100 from monitoring the insulation of the first zone Z1 and the second zone Z2.

In this way, one of the first channel unit 110 and the second channel unit 120 can be connected to the monitoring unit 130 when the first protection device 11 and the second protection device 12 are open, and can be disconnected from the monitoring unit 130 when the first protection device 11 and the second protection device 12 are closed.

When the first protection device 11 and the second protection device 12 are open and one of the first channel unit 110 and the second channel unit 120 is connected to the monitoring unit 130, as shown in FIGS. 5 and 6, the monitoring unit 130 can monitor the insulation of the zone corresponding to the connected channel unit, and when the first protection device 11 and the second protection device 12 are closed and the first channel unit 110 and the second channel unit 120 are not connected to the monitoring unit 130, as shown in FIG. 7, a second insulation monitoring device 200 connected to the electric path between the second protection device 12 and the load L can monitor the insulation of the system 1000.

In the insulation monitoring device 100 as described above, the monitoring unit 130 can be connected to one of the first channel unit 110 and the second channel unit 120 according to a signal received from the power conversion device 10, a control device controlling the power conversion device 10, or an operating device of the system 1000, so as to determine the insulation status of one of the first zone Z1 and the second zone Z2.

Hereinafter, for the convenience of explanation, a description will focus on an example in which the monitoring unit 130 operates based on a signal received from the power conversion device 10; however, the operation of the monitoring unit 130 may also be performed based on a signal received from the control device that controls the power conversion device 10 or the operating device of the system 1000.

The monitoring unit 130 may monitor the insulation of one of the first zone Z1 or the second zone Z2 by determining the insulation status of the one of the first zone Z1 and the second zone Z2.

When receiving a first operation signal from the power conversion device 10, the monitoring unit 130 may be connected to the first channel unit 110 and determine the insulation status of the first zone Z1 based on the measurement signal received from the ground PE or the first channel unit 110.

That is, when receiving the first operation signal, the monitoring unit 130 may be connected to the first channel unit 110 and disconnected from the second channel unit 120, as shown in FIG. 5, and may monitor the insulation of the first zone Z1 by determining the insulation status of the first zone Z1 based on the measurement signal received from the ground PE or the first channel unit 110.

In this case, the monitoring unit 130 may receive the measurement signal from the first channel unit 110 when applying the predetermined signal to the ground PE, and may receive the measurement signal from the ground PE when applying the predetermined signal to the first channel unit 110.

Here, the first operation signal may be transmitted to the monitoring unit 130 while the first protection device 11 and the second protection device 12 are open.

The first operation signal may also be transmitted to the monitoring unit 130 when monitoring the insulation of the first zone Z1.

When receiving a second operation signal from the power conversion device 10, the monitoring unit 130 may be connected to the second channel unit 120 and determine the insulation status of the second zone Z2 based on the measurement signal received from the ground PE or the second channel unit 120.

That is, when receiving the second operation signal, the monitoring unit 130 may be connected to the second channel unit 120 and disconnected from the first channel unit 110, as shown in FIG. 6, and may monitor the insulation of the second zone Z2 by determining the insulation status of the second zone Z2 based on the measurement signal received from the ground PE or the second channel unit 120.

In this case, the monitoring unit 130 may receive the measurement signal from the second channel unit 120 when applying the predetermined signal to the ground PE, and may receive the measurement signal from the ground PE when applying the predetermined signal to the second channel unit 120.

Here, the second operation signal may be transmitted to the monitoring unit 130 while the first protection device 11 and the second protection device 12 are open.

The second operation signal may also be transmitted to the monitoring unit 130 when monitoring the insulation of the second zone Z2.

In this way, the monitoring unit 130 that is connected to one of the first channel unit 110 and the second channel unit 120 and receives the measurement signal to determine the insulation status of one of the first zone Z1 and the second zone Z2 can calculate the magnitude of insulation resistance in a zone corresponding to the connected channel unit based on the measurement signal and determine the insulation status of the zone corresponding to the connected channel unit based on the magnitude of the insulation resistance.

For example, the magnitude of the insulation resistance may be compared with a predetermined reference value. When the magnitude of the insulation resistance is greater than or equal to the predetermined reference value as a result of the comparison, the insulation status of the zone corresponding to the connected channel unit may be determined to be abnormal. On the other hand, when the magnitude of the insulation resistance is smaller than the predetermined reference value, the insulation status of the zone corresponding to the connected channel unit may be determined to be normal.

Here, the magnitude of the insulation resistance may be calculated based on a voltage of the measurement signal, a voltage of the predetermined signal, and a magnitude of internal resistance of an electric path through which the predetermined signal passes, and the predetermined reference value may include a plurality of reference values corresponding to a plurality of resistance values, respectively.

When receiving a third operation signal from the power conversion device 10, the monitoring unit 130 may not be connected to the first channel unit 110 and the second channel unit 120, and thus may not determine the insulation status of the first zone Z1 and the second zone Z2.

That is, when receiving the third operation signal, as shown in FIG. 7, the monitoring unit 130 may be disconnected from the first channel unit 110 and the second channel unit 120, and thus may not monitor the insulation of the first zone Z1 and the second zone Z2.

In this case, the second insulation monitoring device 200 may monitor the insulation of the first zone Z1 and the second zone Z2 by determining the insulation status of an entire zone including the first zone Z1 and the second zone Z2 in a load zone ZL.

Here, the third operation signal may be transmitted to the monitoring unit 130 while the first protection device 11 and the second protection device 12 are closed.

The third operation signal may also be transmitted to the monitoring unit 130 when the power conversion device 10 performs a power conversion operation.

The insulation monitoring device 100 described above may be applied to an insulation monitoring system 1000 and an insulation monitoring method according to embodiments to be described below, or may be implemented by applying the embodiments to be described below, and may also be implemented independently of the embodiments to be described below.

### Insulation Monitoring System

Hereinafter, an insulation monitoring system according to an embodiment will be described, but any part that overlaps the contents of the insulation monitoring device 100 described above will be omitted on the premise that the description of the insulation monitoring device 100 is equally applicable.

The insulation monitoring system 1000 according to the embodiment may be a system that monitors insulation in the (power) system 1000 as shown in FIG. 4.

The insulation monitoring system 1000 includes the transformer 1 that transmits a three-phase AC voltage, the power conversion device 10 that receives the AC voltage from the transformer 1 and converts the AC voltage into a DC voltage, the first insulation monitoring device 100 that monitors the insulation of a primary-side electric path Z1 of the power conversion device 10, the coupling device CL that receives a signal from a secondary-side electric path Z2 of the power conversion device 10, and the second insulation monitoring device 200 that monitors the insulation of a load-side electric path ZL receiving the DC voltage from the power conversion device 10.

That is, the insulation monitoring system 1000 may be configured such that the first insulation monitoring device 100 monitors the insulation of the primary-side electric path Z1 and the secondary-side electric path Z2, and the second insulation monitoring device 200 monitors the insulation of the load-side electric path ZL.

In the insulation monitoring system 1000, the first insulation monitoring device 100 includes the first channel unit 110 that receives a signal from the primary-side electric path Z1, the second channel unit 120 that receives a signal, which is received from the secondary-side electric path Z2, from the coupling device CL, the signal unit 131 that applies the predetermined signal to the ground PE, which is not connected to the primary-side electric path Z1 and the secondary-size electric path Z2, the control unit 132 that is connected to one of the first channel unit 110 and the second channel unit 120 to receive the measurement signal corresponding to the predetermined signal from the connected channel unit and determine the insulation status of the electric path corresponding to the connected channel unit based on the measurement signal, and the connecting unit 133 that connects the first channel unit 110 to the control unit 132 upon monitoring the primary-side electric path Z1 and connects the second channel unit 120 to the control unit 132 upon monitoring the secondary-side electric path Z2.

That is, the first insulation monitoring device 100 may include the first channel unit 110, the second channel unit 120, the signal unit 131, the control unit 132, and the connecting unit 133, to monitor the insulation by determining the insulation status of any one electric path of the primary-side electric path Z1 and the secondary-side electric path Z2.

The insulation monitoring system 1000 may further include the first protection device 11 that connects or disconnects the transformer 1 to or from the power conversion device 10 in the primary-side electric path Z1, and the second protection device 12 that connects or disconnects the power conversion device 10 to or from the load L in the secondary-side electric path Z2.

In this case, the first insulation monitoring device 100 may be connected to an electric path between the transformer 1 and the first protection device 11, the coupling device CL may be connected to an electric path between the power conversion device 10 and the second protection device 12, and the second insulation monitoring device 200 may be connected to an electric path between the second protection device 12 and the load L.

The connecting unit 133, as shown in FIGS. 5 and 6, may connect the control unit 132 to one of the first channel unit 110 and the second channel unit 120 when the first protection device 11 disconnects the transformer 1 from the power conversion device 10 and the second protection device 12 disconnects the power conversion device 10 from the load L.

As the control unit 132 is connected to one of the first channel unit 110 and the second channel unit 120 while the first protection device 11 and the second protection device 12 are open, the first insulation monitoring device 100 can determine the insulation status of one of the electric path between the transformer 1 and the first protection device 11 in the primary-side electric path Z1 and the electric path between the power conversion device 10 and the second protection device 12 in the secondary-side electric path Z2.

In this case, the second insulation monitoring device 200 may determine the insulation status of the load-side electric path ZL between the second protection device 12 and the load L in the secondary-side electric path Z2.

The connecting unit 133, as shown in FIGS. 7, may disconnect the first channel unit 110 and the second channel unit 120 from the control unit 132 when the first protection device 11 connects the transformer 1 to the power conversion device 10 and the second protection device 12 connects the power conversion device 10 to the load L.

Accordingly, the first insulation monitoring device 100 can determine the insulation status of one of the electric path between the transformer 1 and the first protection device 11 in the primary-side electric path Z1 and the electric path between the power conversion device 10 and the second protection device 12 in the secondary-side electric path Z2 by disconnecting the control unit 132 from the first channel unit 110 and the second channel unit 120 while the first protection device 11 and the second protection device 12 are closed.

In this case, the second insulation monitoring device 200 may determine the insulation status of the secondary-side electric path Z2 between the primary-side electric path Z1 and the load-side electric path Z2.

The connecting unit 133 may include the first switching portion 133-1 and the second switching portion 133-2, as shown in FIGS. 5 to 7.

The first switching portion 133-1 may connect the first channel unit 110 to the control unit 132 when monitoring the primary-side electric path Z1, and may disconnect the first channel unit 110 from the control unit 132 when monitoring the secondary-side electric path Z2.

Here, when monitoring the primary-side electric path Z1, the first protection device 11 and the second protection device 12 may be in an open state.

The first switching portion 133-1 may also disconnect the first channel unit 110 from the control unit 132 when the first protection device 11 and the second protection device 12 are closed.

The second switching portion 133-2 may connect the second channel unit 120 to the control unit 132 when monitoring the secondary-side electric path Z2, and may disconnect the second channel unit 120 from the control unit 132 when monitoring the primary-side electric path Z1.

Here, when monitoring the secondary-side electric path Z2, the first protection device 11 and the second protection device 12 may be in an open state.

The second switching portion 133-2 may also disconnect the second channel unit 120 from the control unit 132 when the first protection device 11 and the second protection device 12 are closed.

As such, in the first insulation monitoring device 100, the first switching portion 133-1 may connect the first channel unit 110 to the control unit 132 and the second switching portion 133-2 may disconnect the second channel unit 120 from the control unit 132, as shown in FIG. 5, when monitoring the primary-side electric path Z1, the first switching portion 133-1 may disconnect the first channel unit 110 from the control unit 132 and the second switching portion 133-2 may connect the second channel unit 120 to the control unit 132, as shown in FIG. 6, when monitoring the secondary-side electric path Z2, and the first switching portion 133-1 may disconnect the first channel unit 110 from the control unit 132 and the second switching portion 133-2 may disconnect the second channel unit 120 from the control unit 132, as shown in FIG. 7, when the first protection device 11 and the second protection device 12 are closed.

In case of monitoring the primary-side electric path Z1, as shown in FIG. 5, the first switching portion 133-1 may connect the first channel unit 110 to the control unit 132 and the signal unit 131 may apply the predetermined signal to the ground PE, such that the first channel unit 110 may receive the measurement signal from the primary-side electric path Z1 and the control unit 132 may receive the measurement signal from the first channel unit 110. Accordingly, the first insulation monitoring device 100 can determine the insulation status of the primary-side electric path Z1 based on the measurement signal.

That is, when monitoring the primary-side electric path Z1, as shown in FIG. 5, the control unit 132 may be connected to the first channel unit 110 and disconnected from the second channel unit 120, to monitor the insulation of the primary-side electric path Z1 by determining the insulation status of the primary-side electric path Z1 based on the measurement signal received from the first channel unit 110.

In case of monitoring the secondary-side electric path Z2, as shown in FIG. 6, the second switching portion 133-2 may connect the second channel unit 120 to the control unit 132 and the signal unit 131 may apply the predetermined signal to the ground PE, such that the second channel unit 120 may receive the measurement signal from the secondary-side electric path Z2 and the control unit 132 may receive the measurement signal from the second channel unit 120. Accordingly, the first insulation monitoring device 100 can determine the insulation status of the secondary-side electric path Z2 based on the measurement signal.

That is, when monitoring the secondary-side electric path Z2, as shown in FIG. 6, the control unit 132 may be connected to the second channel unit 120 and disconnected from the first channel unit 110, to monitor the insulation of the secondary-side electric path Z2 by determining the insulation status of the secondary-side electric path Z2 based on the measurement signal received from the second channel unit 120.

In this way, the control unit 132 which is connected to one of the first channel unit 110 and the second channel unit 120 and receives the measurement signal to determine the insulation status of one of the primary-side electric path Z1 and the secondary-side electric path Z2 can calculate the magnitude of insulation resistance in an electric path corresponding to the connected channel unit based on the measurement signal and determine the insulation status of the electric path corresponding to the connected channel unit based on the magnitude of the insulation resistance.

When the power conversion device 10 is in operation, as shown in FIG. 7, the first switching portion 133-1 may disconnect the first channel unit 110 from the control unit 132, and the second switching unit 133-2 may disconnect the second channel unit 120 from the control unit 132, suppressing the first insulation monitoring device 100 from determining the insulation status of the primary-side electric path Z1 and the secondary-side electric path Z2.

In this case, the second insulation monitoring device 200 may determine the insulation status of an entire zone including the primary-side electric path Z1 and the secondary-side electric path Z2 in the load-side electric path ZL.

The insulation monitoring device 1000 described above may be applied to the insulation monitoring device 100 according to the embodiment described above and an insulation monitoring method according to an embodiment to be described below, or may be implemented by applying the embodiments described above or embodiments to be described below, and may also be implemented independently of the embodiments described above or the embodiments to be described below.

### Insulation Monitoring Method

Hereinafter, an insulation monitoring method according to an embodiment will be described, but any part that overlaps the contents of the insulation monitoring device 100 and the insulation monitoring system 1000 described above will be omitted on the premise that the descriptions of the insulation monitoring device 100 and the insulation monitoring system 1000 are equally applicable.

An insulation monitoring method according to an embodiment, as shown in FIG. 4, may be an insulation monitoring method performed by the insulation monitoring device 100, which includes the first channel unit 110 receiving a signal from a first electric path Z1 between the transformer 1 and the power conversion device 10 in the system 1000, the second channel unit 120 receiving a signal from the coupling device CL, which receives a signal from a second electric path Z2 between the power conversion device 10 and the load L in the system 1000, and the monitoring unit 130 applying the predetermined signal to the ground PE to which an electric path of the system 1000 is not connected, to determine the insulation status of one of the first electric path Z1 and the second electric path Z2 based on a signal received from the one of the first channel unit 110 and the second channel unit 120.

The insulation monitoring method may be a method performed by the monitoring unit 130 of the insulation monitoring device 100.

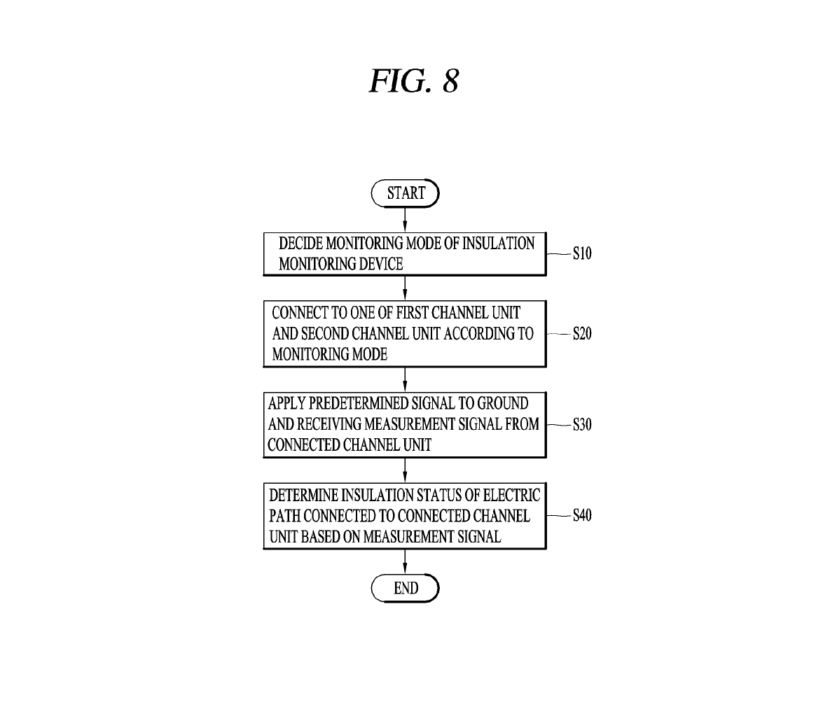

The insulation monitoring method includes, as shown in FIG. 8, deciding a monitoring mode of the insulation monitoring device 100 (S10), connecting to one of the first channel unit 110 and the second channel unit 120 according to the monitoring mode (S20), applying the predetermined signal to the ground PE to receive the measurement signal corresponding to the predetermined signal from the connected channel unit (S30), and determining an insulation status of an electric path connected to the connected channel unit based on the measurement signal (S40).

Here, the monitoring mode may be a mode for monitoring one of the first electric path Z1 and the second electric path Z2 while the power conversion device 10 is not in operation.

The monitoring mode may include, for example, a first mode for monitoring the first electric path Z1 and a second mode for monitoring the second electric path Z2.

The deciding step (S10) may be to decide the monitoring mode according to the signal received by the monitoring unit 130 from the power conversion device 10.

Here, the signal received from the power conversion device 10 may be a signal regarding the operating state of the power conversion device 10.

Accordingly, when the monitoring unit 130 receives a signal regarding a non-operating state from the power conversion device 10, the monitoring unit 130 may decide a mode for monitoring one of the first electric path Z1 and the second electric path Z2.

The connecting step (S20) may be to connect the monitoring unit 130 to one of the first channel unit 110 and the second channel unit 120 according to a result of the decision in the deciding step (S10).

The connecting step (S20) may be to connect the monitoring unit 130 to the first channel unit 110 when the monitoring mode is a mode for monitoring the first electric path Z1.

The connecting step (S20) may be to connect the monitoring unit 130 to the second channel unit 120 when the monitoring mode is a mode for monitoring the second electric path Z2.

The receiving step (S30) may be to receive the measurement signal from the channel unit connected in the connecting step (S20), in response to the monitoring unit 130 applying the predetermined signal to the ground PE.

The receiving step (S30) may be to receive the measurement signal from the first channel unit 110 when the monitoring mode is a mode for monitoring the first electric path Z1.

The receiving step (S30) may be to receive the measurement signal from the second channel unit 120 when the monitoring mode is a mode for monitoring the second electric path Z2.

The determining step (S40) may be to allow the monitoring unit 130 to determine the insulation status of the electric path connected to the connected channel unit based on the measurement signal received in the receiving step (S30).

The determining step (S40) may be to determine the insulation status of the first electric path Z1 based on the measurement signal received from the first channel unit 110 when the monitoring mode is the mode for monitoring the first electric path Z1.

The determining step (S40) may be to determine the insulation status of the second electric path Z2 based on the measurement signal received from the second channel unit 120 when the monitoring mode is the mode for monitoring the second electric path Z2.

The determining step (S40) may be to calculate magnitude of insulation resistance of the electric path connected to the connected channel unit based on the measurement signal, and determine the insulation status of the electric path connected to the connected channel unit based on the magnitude of the insulation resistance.

That is, the monitoring unit 130 may monitor the insulation of a zone corresponding to the connected channel unit.

The insulation monitoring method described above can be implemented as computer-readable codes in a program-recorded medium.

Here, the computer-readable medium may include all types of recording devices, such as hard disk drive (HDD), solid state disk (SSD), silicon disk drive (SDD), ROM, RAM, CD-ROM, magnetic tape, floppy disk, optical data storage device, etc., in which data which is readable by a computer system is stored, and may also include those implemented in the form of a carrier wave (e.g., transmission via the Internet), and the computer may include the control unit 132 of the insulation monitoring device 100.

So far, the embodiments of the insulation monitoring device 100, the insulation monitoring system 1000, and the insulation monitoring method have been described, but the described embodiments may be modified in various ways without departing from the scope of the disclosure, and the scope of the disclosure should not be limited to the described embodiments, but should be determined by the claims described below as well as equivalents of the claims.

What is claimed is:

1. An insulation monitoring device configured to monitor insulation of a system, the device comprising:
a first channel unit connected to an electric path of a first zone between a transformer and a power conversion device in the system;
a second channel unit connected to a coupling device connected to an electric path of a second zone between the power conversion device and a load in the system; and
a monitoring unit connected to a ground that is not connected to an electric path of the system, connected to one of the first channel unit and the second channel unit according to an operation signal transmitted from the power conversion device, and configured to apply a predetermined signal to one of the ground and the connected channel unit, receive a measurement signal corresponding to the predetermined signal from another channel unit, and determine an insulation status of a zone corresponding to the connected channel unit based on the measurement signal.

2. The insulation monitoring device of claim 1, wherein
a first protection device is arranged in the first zone to connect or disconnect the transformer to or from the power conversion device, and
the first channel unit is connected to an electric path between the transformer and the first protection device.

3. The insulation monitoring device of claim 2, wherein
one of the first channel unit and the second channel unit is connected to the monitoring unit while the first protection device is open.

4. The insulation monitoring device of claim 1, wherein
a second protection device is arranged in the second zone to connect or disconnect the power conversion device to or from the load, and
the second channel unit is connected to an electric path between the power conversion device and the second protection device through the coupling device.

5. The insulation monitoring device of claim 4, wherein
one of the first channel unit and the second channel unit is connected to the monitoring unit while the second protection device is open.

6. The insulation monitoring device of claim 1, wherein
the first channel unit and the second channel unit are disconnected from the monitoring unit in a state where a first protection device arranged in the first zone to connect or disconnect the transformer to or from the power conversion device and a second protection device arranged in the second zone to connect or disconnect the power conversion device to or from the load are closed.

7. The insulation monitoring device of claim 1, wherein
the monitoring unit is connected to the first channel unit to determine an insulation status of the first zone based on the measurement signal received from the ground or the first channel unit
when receiving a first operation signal from the power conversion device, and
connected to the second channel unit to determine an insulation status of the second zone based on the measurement signal received from the ground or the second channel unit when receiving a second operation signal from the power conversion device.

8. The insulation monitoring device of claim 1, wherein
the monitoring unit calculates magnitude of insulation resistance of a zone corresponding to the connected channel unit based on the measurement signal, and determines an insulation status of the zone corresponding to the connected channel unit based on the magnitude of the insulation resistance.

9. An insulation monitoring system comprising:
a transformer configured to transmit a three-phase alternating current (AC) voltage;
a power conversion device configured to receive the AC voltage from the transformer and convert the AC voltage into a direct current (DC) voltage;
a first insulation monitoring device configured to monitor insulation of a primary-side electric path of the power conversion device;
a coupling device configured to receive a signal from a secondary-side electric path of the power conversion device; and
a second insulation monitoring device configured to monitor insulation of a load-side electric path receiving the DC voltage from the power conversion device,
wherein the first insulation monitoring device comprises:
a first channel unit configured to receive a signal from the primary-side electric path;
a second channel unit configured to receive a signal, which is received from the secondary-side electric path, from the coupling device;
a signal unit configured to apply a predetermined signal to a ground which is not connected to the primary-side electric path and the secondary-side electric path;
a control unit connected to one of the first channel unit and the second channel unit, and configured to receive a measurement signal corresponding to the predetermined signal from the connected channel unit, and determine an insulation status of an electric path corresponding to the connected channel unit based on the measurement signal; and
a connecting unit configured to connect the first channel unit to the control unit when monitoring the primary-side electric path, and connect the second channel unit to the control unit when monitoring the secondary-side electric path.

10. The insulation monitoring system of claim 9, further comprising:
a first protection device configured to connect or disconnect the transformer to or from the power conversion device in the primary-side electric path; and
a second protection device configured to connect or disconnect the power conversion device to or from the load in the secondary-side electric path,
wherein the first insulation monitoring device is connected to an electric path between the transformer and the first protection device,
the coupling device is connected to an electric path between the power conversion device and the second protection device, and
the first insulation monitoring device is connected to an electric path between the second protection device and the load.

11. The insulation monitoring system of claim 10, wherein
the connecting unit disconnects the first channel unit and the second channel unit from the control unit when the first protection device connects the transformer to the power conversion device and the second protection device connects the power conversion device to the load.

12. The insulation monitoring system of claim 9, wherein
the connecting unit comprises:
a first switching portion configured to connect the first channel unit to the control unit when monitoring the primary-side electric path, and disconnect the first channel unit from the control unit when monitoring the secondary-side electric path; and
a second switching portion configured to connect the second channel unit to the control unit when monitoring the secondary-side electric path and disconnect the second channel unit from the control unit when monitoring the primary-side electric path.

13. An insulation monitoring method of an insulation monitoring device comprising
a first channel unit configured to receive a signal from a first electric path between a transformer and a power conversion device in a system,
a second channel unit configured to receive a signal from a coupling device that receives a signal from a second electric path between the power conversion device and a load in the system, and
a monitoring unit configured to apply a predetermined signal, to a ground to which an electric path of the system is not connected, to determine an insulation status of one of the first electric path and the second electric path based on a signal received from one of the first channel unit and the second channel unit, the method comprising:
deciding a monitoring mode of the insulation monitoring device;
connecting to one of the first channel unit and the second channel unit according to the monitoring mode;
applying the predetermined signal to the ground to receive a measurement signal corresponding to the predetermined signal from a connected channel unit; and
determining an insulation status of an electric path connected to the connected channel unit based on the measurement signal.

14. The insulation monitoring method of claim 13, wherein
the monitoring mode is a mode for monitoring one of the first electric path and the second electric path while the power conversion device is not in operation.

15. The insulation monitoring method of claim 14, wherein
the connecting step is to connect to the first channel unit when the monitoring mode is a mode for monitoring the first electric path, and
to connect to the second channel unit when the monitoring mode is a mode for monitoring the second electric path.
